(19) United States
(12) Patent Application Publication
(10) Pub. No.: US 2026/0164866 A1
(43) Pub. Date: Jun. 11, 2026

(54) DISPLAY PANEL AND DISPLAY DEVICE

(71) Applicant: BOE TECHNOLOGY GROUP CO., LTD., Beijing (CN)

(72) Inventors: Yuwei YAN, Beijing (CN); Jintao PENG, Beijing (CN); Kai GUO, Beijing (CN); Zhiqiang XU, Beijing (CN); Wanpeng TENG, Beijing (CN); Chunfang ZHANG, Beijing (CN); Weixing LIU, Beijing (CN); Meirong LU, Beijing (CN); Huanhuan WANG, Beijing (CN)

(73) Assignee: BOE TECHNOLOGY GROUP CO., LTD., Beijing (CN)

(21) Appl. No.: 18/705,614

(22) PCT Filed: Jul. 20, 2023
(86) PCT No.: PCT/CN2023/108324

§ 371 Date: Apr. 29, 2024

(51) Int. Cl. H10H 20/857; H10H 20/01; H10H 20/813; H10H 20/84

(52) U.S. Cl. CPC H10H 20/857; H10H 20/017; H10H 20/0364; H10H 20/8131; H10H 20/84

(57) ABSTRACT

Provided is a display pane. The display panel includes a substrate; a plurality of pixel units arranged in an array disposed on a side of the substrate, wherein each of the plurality of pixel units includes a plurality of light-emitting structures stacked, and areas of orthographic projections of the plurality of light-emitting structures on the substrate gradually decrease along a direction away from the substrate; and at least two first metal connectors in one-to-one correspondence with at least two of the pixel units. Each of the first metal connectors is simultaneously electrically connected to a first semiconductor layer of each of the light-emitting structures in the corresponding pixel unit, and the first metal connectors are electrically connected to the substrate. The substrate is configured to provide a same signal to the at least two first metal connectors.

### CROSS-REFERENCE TO RELATED APPLICATION

The application is a U.S. national stage of international application No. PCT/CN2023/108324, filed on Jul. 20, 2023, the content of which is herein incorporated by reference in its entirety.

### TECHNICAL FIELD

The present disclosure relates to the field of display technologies, and in particular, relates to a display panel and a display device.

### BACKGROUND

With the rise of emerging technologies such as smart wearable devices, augmented reality, and virtual reality, high-end display technology has become an urgent need in the market. Micro-light emitting diode (Micro-LED) is a new generation of display technology with self-luminous display characteristics. Micro LED display devices have the advantages of higher brightness and stability, better luminous efficiency, lower power consumption, and faster response.

### SUMMARY

Embodiments of the present disclosure provide a display panel. The technical solutions are as follows.

According to some embodiments of the present disclosure, a display panel is provided. The display panel includes:
a substrate;
a plurality of pixel units arranged in an array disposed on a side of the substrate, wherein each of the plurality of pixel units includes a plurality of light-emitting structures stacked, and areas of orthographic projections of the plurality of light-emitting structures on the substrate gradually decrease along a direction away from the substrate; and
at least two first metal connectors in one-to-one correspondence with at least two of the pixel units, wherein each of the first metal connectors is simultaneously electrically connected to a first semiconductor layer of each of the light-emitting structures in the corresponding pixel unit, and the first metal connectors are electrically connected to the substrate;
wherein the substrate is configured to provide a same signal to the at least two first metal connectors.

In some embodiments, the first metal connector includes a first connection portion and a second connection portion that are connected to each other; wherein an orthographic projection of the first connection portion on the substrate is within an orthographic projection of the pixel unit on the substrate, and an orthographic projection of the second connection portion on the substrate is outside the orthographic projection of the pixel unit on the substrate; and
the first connection portion is electrically connected to the first semiconductor layer of each of the light-emitting structures in the pixel unit, and an end, facing away from the first connection portion, of the second connection portion is electrically connected to the substrate.

In some embodiments, an orthographic projection of the first metal connector on the substrate is fully within an orthographic projection of the pixel unit on the substrate; and the display panel further includes a first wire, wherein one end of the first wire is electrically connected to the first metal connector, and the other end of the first wire is electrically connected to the substrate.

In some embodiments, a first through-hole running successively through each of the light-emitting structures is formed in the pixel unit, and the other end of the first wire is electrically connected to the substrate after running through the first through-hole.

In some embodiments, the display panel further includes: a plurality of second metal connectors in one-to-one correspondence with the plurality of light-emitting structures in one of the pixel units, wherein each of the second metal connectors is electrically connected to a second semiconductor layer of the corresponding light-emitting structure and electrically connected to the substrate.

In some embodiments, each of the second metal connectors includes a third connection portion and a fourth connection portion that are connected to each other, wherein an orthographic projection of the third connection portion on the substrate is within an orthographic projection of the pixel unit on the substrate, and an orthographic projection of the fourth connection portion on the substrate is outside the orthographic projection of the pixel unit on the substrate; and
the third connection portion is electrically connected to the second semiconductor layer of the corresponding light-emitting structure, and an end, facing away from the third connection portion, of the fourth connection portion is electrically connected to the substrate.

In some embodiments, orthographic projections of the second metal connectors on the substrate are all within an orthographic projection of the pixel unit on the substrate; and the display panel further includes a second wire, wherein one end of the second wire is electrically connected to the second metal connector, and the other end of the second wire is electrically connected to the substrate.

In some embodiments, wherein a second through-hole is formed in the pixel unit, wherein the second through-hole runs through at least the light-emitting structure closest to the substrate in the pixel unit, and the other end of the second wire is electrically connected to the substrate after running through the second through-hole.

In some embodiments, the pixel unit further includes a plurality of drive electrode layers; wherein the plurality of drive electrode layers are in one-to-one correspondence with the plurality of light-emitting structures, each of the drive electrode layers is disposed on a side, close to the substrate, of the corresponding light-emitting structure and lapped with a side, facing away from the first semiconductor layer, of the second semiconductor layer in the corresponding light-emitting structure, the plurality of drive electrode layers are in one-to-one correspondence with the plurality of second metal connectors, and each of the second metal connectors is lapped with the corresponding drive electrode layer.

In some embodiments, a portion of an orthographic projection of the drive electrode layer on the substrate is outside an orthographic projection of the corresponding light-emitting structure on the substrate; and at least a portion of the second metal connectors is disposed on a side, facing away from the substrate, of the corresponding drive electrode layer and lapped with a portion, not covered by the corresponding light-emitting structure, of the drive electrode layer.

In some embodiments, for a first drive electrode layer and a second drive electrode layer that are adjacent to each other in the pixel unit and a light-emitting structure disposed between the first drive electrode layer and the second drive electrode layer, an orthographic projection of the light-emitting structure on the substrate is within an orthographic projection of the first drive electrode layer on the substrate, an orthographic projection of the second drive electrode layer on the substrate is within the orthographic projection of the light-emitting structure on the substrate, and the orthographic projections of the first drive electrode layer, the light-emitting structure, and the second drive electrode layer on the substrate successively decrease;
wherein the first drive electrode layer is closer to the substrate relative to the second drive electrode layer.

In some embodiments, the plurality of light-emitting structures in the pixel unit include a first light-emitting structure and at least one second light-emitting structure, the first light-emitting structure being a light-emitting structure, farthest from the substrate, among the plurality of light-emitting structures, and the at least one second light-emitting structure being a light-emitting structure disposed between the first light-emitting structure and the substrate; and
a portion of the first metal connector is disposed on a side, facing away from the substrate, of the second light-emitting structure and lapped with a portion, not covered by the second drive electrode layer, of the first semiconductor layer of the second light-emitting structure.

In some embodiments, the pixel unit further includes a common electrode layer disposed on a side, facing away from the substrate, of the first light-emitting structure, wherein the common electrode layer is lapped with a side, facing away from the second semiconductor layer, of the first semiconductor layer in the first light-emitting structure, and an orthographic projection of the common electrode layer on the substrate is within an orthographic projection of the first light-emitting structure on the substrate;
wherein a portion of the first metal connector is disposed on a side, facing away from the first light-emitting structure, of the common electrode layer and lapped with the common electrode layer.

In some embodiments, the light-emitting structure includes the first semiconductor layer and the second semiconductor layer that are opposite to each other and a light-emitting layer disposed between the first semiconductor layer and the second semiconductor layer, the second semiconductor layer being closer to the substrate relative to the first semiconductor layer.

In some embodiments, the display panel further includes: a first insulative layer, the first insulative layer covering a side surface of the light-emitting structure and covering at least a portion of a surface, facing away from the substrate, of the light-emitting structure;
wherein the first insulative layer has a plurality of first vias and a plurality of second vias therein, the first metal connector is electrically connected to the first semiconductor layers of the plurality of light-emitting structures through the plurality of first vias, and the plurality of second metal connectors are electrically connected to the second semiconductor layers of the plurality of light-emitting structures through the plurality of second vias.

In some embodiments, in a case where the pixel unit has a through-hole therein, the first insulative layer covers an inner wall of the through-hole.

In some embodiments, the pixel unit further includes a transparent bonding layer disposed between adjacent two of the light-emitting structures, and a reflective bonding layer disposed between the light-emitting structure and the substrate.

In some embodiments, for two adjacent light-emitting structures of the light-emitting structures in the pixel unit, an outer boundary of an orthographic projection of one of the two light-emitting structures on the substrate is not overlapped with an outer boundary of an orthographic projection of the other of the two light-emitting structures on the substrate; alternatively, an outer boundary of a portion of the orthographic projection of one of the two light-emitting structures on the substrate is overlapped with an outer boundary of a portion of the orthographic projection of the other of the two light-emitting structures on the substrate.

In some embodiments, the substrate includes a plurality of drive circuits in one-to-one correspondence with the plurality of light-emitting structures in one of the pixel units and a common signal connection terminal, wherein each of the drive circuits is electrically connected to the corresponding light-emitting structure by the second metal connector, and the at least two first metal connectors are all electrically connected to the common signal connection terminal.

According to some embodiments of the present disclosure,, a display device is provided. The display device includes:
a display panel, wherein the display panel is the display panel as described above.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a top view of a display panel according to some embodiments of the present disclosure;

FIG. 2 is a top view of a partial structure of a display panel according to some embodiments of the present disclosure;

FIG. 3 is a sectional view of the display panel illustrated in FIG. 2 along a line A-A′;

FIG. 4 is a top view of a partial structure of another display panel according to some embodiments of the present disclosure;

FIG. 5 is a sectional view of FIG. 4 along a line B-B′;

FIG. 6 is a top view of a partial structure of still another display panel according to some embodiments of the present disclosure;

FIG. 7 is a sectional view of FIG. 6 along a line C-C′;

FIG. 8 is a top view of a partial structure of yet still another display panel according to some embodiments of the present disclosure;

FIG. 9 is a sectional view of FIG. 8 along a line D-D′;

FIG. 10 is a sectional view of FIG. 8 along a line E-E′;

FIG. 11 is a sectional view of a partial structure of a display panel at one view according to some embodiments of the present disclosure;

FIG. 12 is a sectional view of a partial structure of a display panel at another viewing angle according to some embodiments of the present disclosure;

FIG. 13 is a sectional view of FIG. 4 along a line F-F′;

FIG. 14 is a top view of a partial structure of a display panel according to some embodiments of the present disclosure;

FIG. 15 is a flowchart of a method for manufacturing a display panel according to some embodiments of the present disclosure;

FIG. 16 is a film-layer schematic structural diagram of a pixel unit formed on a substrate according to some embodiments of the present disclosure;

FIG. 17 is a film-layer schematic structural diagram where a step structure is formed according to some embodiments of the present disclosure;

FIG. 18 is a film-layer schematic structural diagram where a first insulative layer is formed according to some embodiments of the present disclosure;

FIG. 19 is a film-layer schematic structural diagram where a plurality of first vias and a plurality of second vias are formed according to some embodiments of the present disclosure;

FIG. 20 is a film-layer schematic structural diagram where a first metal connector and a partial second metal connector are formed according to some embodiments of the present disclosure;

FIG. 21 is a film-layer schematic diagram where a second insulative layer is formed according to some embodiments of the present disclosure; and

FIG. 22 is a schematic structural diagram where a second wire is formed according to some embodiments of the present disclosure.

Definite embodiments of the present disclosure, shown by the above-described accompanying drawings, will be described in further detail hereinafter. These accompanying drawings and textual descriptions are not intended to limit the scope of the present disclosure in any form, but rather to illustrate the concepts of the present disclosure for those skilled in the art by reference to particular embodiments.

### DETAILED DESCRIPTION

The present disclosure is described in further detail with reference to the accompanying drawings, to clearly present the objects, technical solutions, and advantages of the present disclosure.

In some practices, a display panel typically includes a substrate, a plurality of pixel units disposed on the substrate, and a common cathode layer disposed on an entire surface. The plurality of pixel units share this common cathode layer provided on the entire surface.

However, the common cathode layer provided on the entire surface of the display panel has a high resistance, and the voltage drop in the common cathode layer is usually more pronounced when further away from the power supply point, resulting in an undesirable phenomenon of uneven light emission in the display panel, which leads to a poor display effect of the display panel.

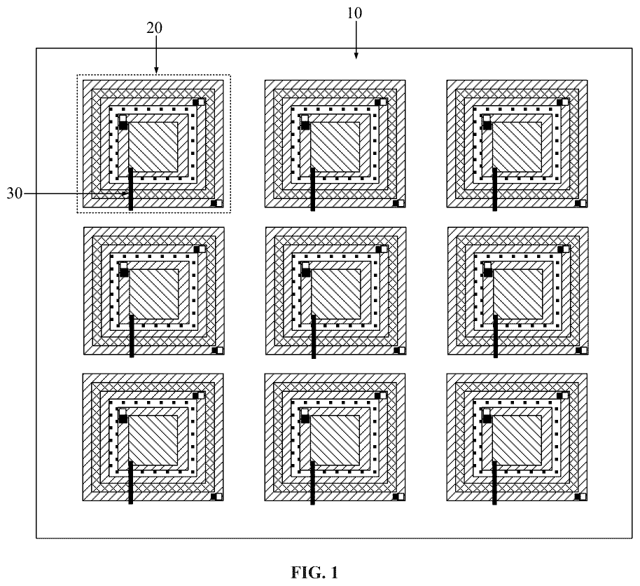

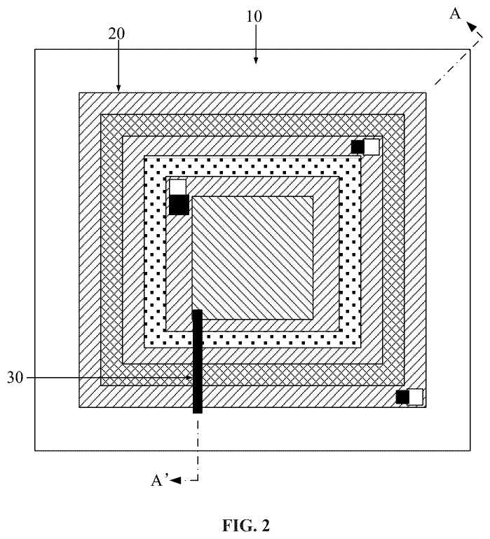

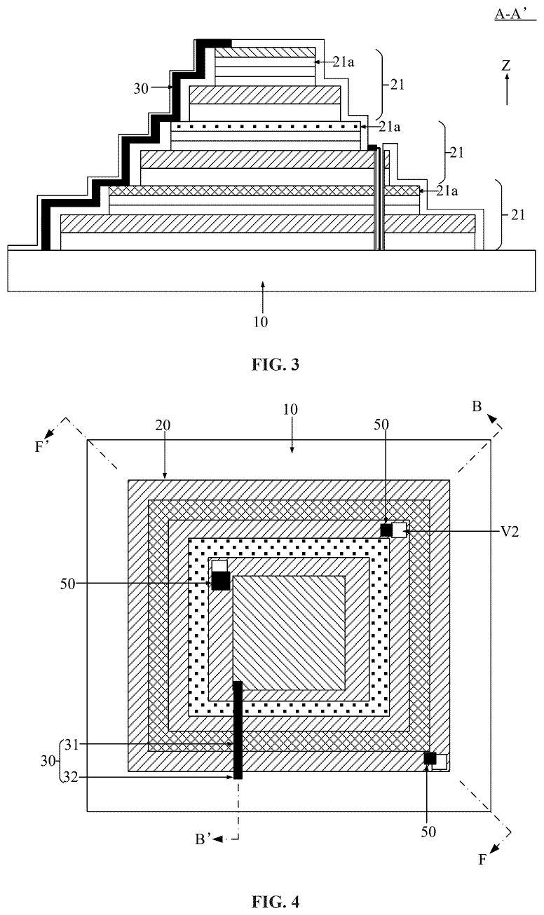

FIG. 1 is a top view of a display panel according to some embodiments of the present disclosure. FIG. 2 is a top view of a partial structure of a display panel according to some embodiments of the present disclosure. FIG. 3 is a sectional view of the display panel illustrated in FIG. 2 along a line A-A′. Referring to FIGS. 1, 2, and 3, the display panel is a display panel integrated into a Micro LED display device. The display panel includes a substrate 10, a plurality of pixel units 20 arranged in an array, and a connector 30.

The array-arranged plurality of pixel units 20 in the display device are disposed on a side of the substrate 10. Each of the pixel units 20 includes a plurality of light-emitting structures 21 stacked arranged. Areas of orthographic projections of the plurality of light-emitting structures 21 on the substrate 10 of the display panel gradually decrease along a direction away from the substrate 10 (Z-axis direction in FIG. 1).

The display device includes at least two first metal connectors 30 in one-to-one correspondence with the at least two pixel units 20. Each of the first metal connectors 30 is electrically connected to first semiconductor layers 21a of the light-emitting structures 21 in the corresponding pixel unit 20 at the same time, and this first metal connector 30 is electrically connected to the substrate 10. In some embodiments, the first metal connector 30 is a strip-like shape. The strip-shaped first metal connector 30 is electrically connected to the first semiconductor layers 21a of the light-emitting structures 21 in the corresponding pixel unit 20 at the same time and is electrically connected to the substrate 10. In some embodiments, each pixel unit of the plurality of pixel units 20 corresponds to one first metal connector 30.

The substrate 10 in the display panel is configured to provide the same signal to at least two first metal connectors 30, such that electrical signals required for light emission are provided to each light-emitting structure 21 in the corresponding pixel units 20 by the first metal connectors 30. In some embodiments, the substrate in the display panel includes a base substrate (not shown in the figure) and a driver integrated into the base substrate. The driver is electrically connected to the plurality of pixel units and the first metal connector to provide the display panel with electrical signals required for proper operation. For example, the base substrate is a plate-like structure made of materials such as silicon, glass, or sapphire, and the driver is bound to a side, facing away from the pixel units, of the base substrate.

In some embodiments of the present disclosure, the plurality of pixel units 20 arranged in an array are disposed on the substrate 10, each of the pixel units 20 includes the plurality of light-emitting structures 21 stacked, and the first metal connector 30 corresponding to this pixel unit 20 is electrically connected to the first semiconductor layers 21a of the light-emitting structures 21 in the pixel unit 20 and electrically connected to the substrate 10. The first metal connector 30 has a smaller resistance with respect to the communally provided cathode layer (e.g., the entire ITO layer) and the conductivity of the first metal connector 30 is high. Therefore, the undesirable phenomenon that the voltage drop is pronounced is effectively avoided, such that the brightness of the screen displayed by the display panel is as uniform as possible, and thus the display effect of the display panel is improved. In addition, by providing the first metal connector 30 instead of providing the common electrode layer on the entire layer, the probability of undesirable phenomena such as large-step breakage of the entire common electrode layer is effectively avoided, such that the display panel has better yield and reliability.

In related art, the plurality of pixel units share a common electrode layer, as a result, the common electrode layer has a large overall area and is prone to large-step breakage. In the present disclosure, each pixel unit uses a separate first metal connector for the electrical connection of the first semiconductor layer of each light-emitting structure, such that the undesirable phenomenon such as generating similar large-step breakage between adjacent pixel units.

In summary, the embodiments of the present disclosure provide a display panel that includes the substrate, the plurality of pixel units, and the first metal connector. The plurality of pixel units arranged in an array are disposed on the substrate, each of the pixel units includes the plurality of light-emitting structures stacked, and the first metal connector corresponding to this pixel unit is electrically connected to the first semiconductor layers of the light-emitting structures in the pixel unit and to the substrate. The first metal connector has a smaller resistance relative to the cathode layer communally provided (e.g., the entire ITO layer), and the conductivity of the first metal connector is high. Therefore, the undesirable phenomenon of a pronounced voltage drop is effectively avoided, such that the brightness of the screen displayed by the display panel is as uniform as possible, and thus the display effect of the display panel is improved. In addition, by providing the first metal connector instead of providing the common electrode layer on the entire layer, the probability of undesirable phenomena such as large-step breakage of the entire common electrode layer is effectively avoided, such that the display panel has a better yield and reliability.

In some embodiments, each pixel unit 20 and the first metal connector 30 are disposed in various optional implementations. The schematic description is given by the following embodiments of the present disclosure using two optional implementations as examples.

For a first optional implementation, refer to FIGS. 4 and 5. FIG. 4 is a top view of a partial structure of another display panel according to some embodiments of the present disclosure. FIG. 5 is a sectional view of FIG. 4 along a line B-B′. The first metal connector 30 in the display panel includes a first connection portion 31 and a second connection portion 32 that are connected to each other. An orthographic projection of the first connection portion 31 of the first metal connector 30 on the substrate 10 is within an orthographic projection of the pixel unit 20 on the substrate 10. An orthographic projection of the second connection portion 32 of the first metal connector 30 on the substrate 10 is outside the orthographic projection of the pixel unit 20 on the substrate 10. The first connection portion 31 in the first metal connector 30 is electrically connected to the first semiconductor layer 21a of each light-emitting structure 21 in the pixel unit 20, and an end, facing away from the first connection portion 31, of the second connection portion 32 in the first metal connector 30 is electrically connected to the substrate 10. In this case, the first connection portion 31 and the second connection portion 32 that are connected to each other are provided in the first metal connector 30, the first connection portion 31 is electrically connected to the first semiconductor layer 21a of each light-emitting structure 21 in the corresponding pixel unit 20, and the second connection portion 32 is electrically connected to the substrate 10. In this way, the substrate 10 is capable of providing electrical signals to the first connection portion 31 over the second connection portion 32, and thus the electrical signals are provided to the first semiconductor layer 21a of each light-emitting structure 21. In addition, the first connection portion 31 and the second connection portion 32 are both provided at an edge position of the pixel unit, such that a light-emitting area of each light-emitting structure is large. It should be noted that the first connection portion 31 and the second connection portion 32 are in a one-piece structure; alternatively, they are formed separately and then fixedly connected by welding or the like.

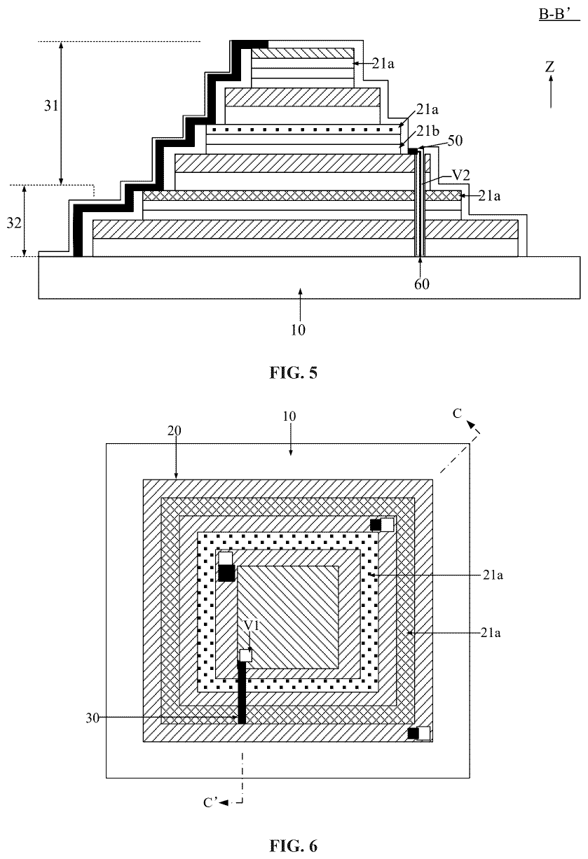

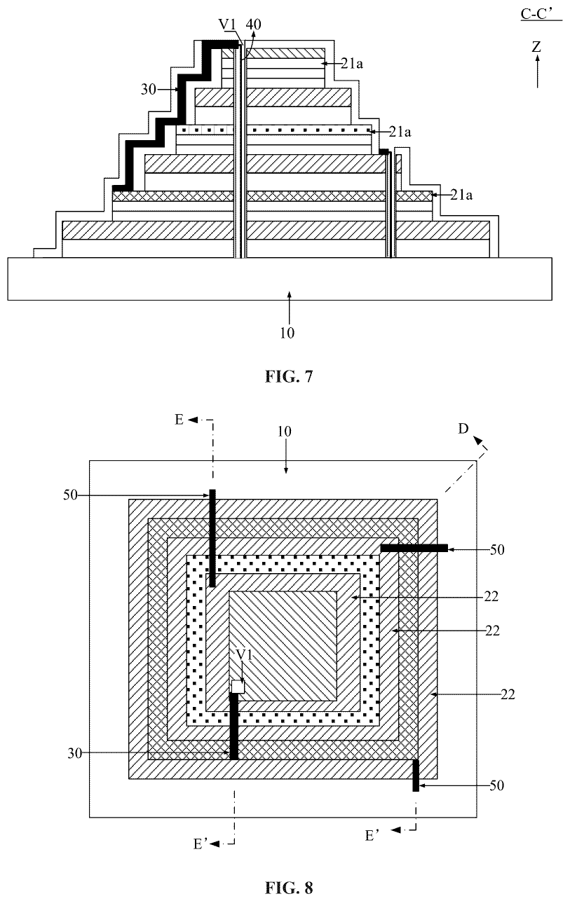

For a second optional implementation, refer to FIGS. 6 and 7. FIG. 6 is a top view of a partial structure of still another display panel according to some embodiments of the present disclosure. FIG. 7 is a sectional view of FIG. 6 along a line C-C′. An orthographic projection of the first metal connector 30 of the display panel on the substrate 10 is within an orthographic projection of a corresponding pixel unit 20 on the substrate 10. The display panel further includes a first wire 40. One end of the first wire 40 is electrically connected to the first metal connector 30, and the other end is electrically connected to the substrate 10. In this case, the orthographic projection of the first metal connector 30 on the substrate 10 is within the orthographic projection of the corresponding pixel unit 20 on the substrate 10, and the first metal connector 30 is led to the substrate 10 by the first wire 40. In this way, a length of the first metal connector 30 in the Z-axis direction is reduced, such that the risk of fracture of the first metal connector 30 is reduced. For example, one end of the first wire 40, after being connected to the first metal connector 30, is electrically connected to the substrate 10 after being bent downward from an outer edge of the pixel unit 20.

In some embodiments of the present disclosure, as shown in FIG. 6 and FIG. 7, a first through-hole V1 is formed in each pixel unit 20. The first through-hole V1 runs successively through the respective light-emitting structures 21 in this pixel unit 20. One end of the first wire 40 in the display panel is electrically connected to the first metal connector 30, and the other end of the first wire 40 is electrically connected to the substrate 10 after running through the first through-hole V1. In this case, by forming the first through-hole V1 running successively through the respective light-emitting structures 21 in the pixel unit 20, after one end of the first wire 40 is electrically connected to the substrate 10, the other end is electrically connected to the substrate 10 after running through the first through-hole V1. In this way, the first wire 40 is integrated inside the pixel unit 20, such that the integration degree of the pixel unit 20 is improved. It should be noted that to avoid the undesirable phenomenon of a short circuit caused by the contact between the first wire 40 and an inner wall of the first through-hole V1, an inner diameter of the first through-hole V1 is defined to be larger than an outer diameter of the first wire 40.

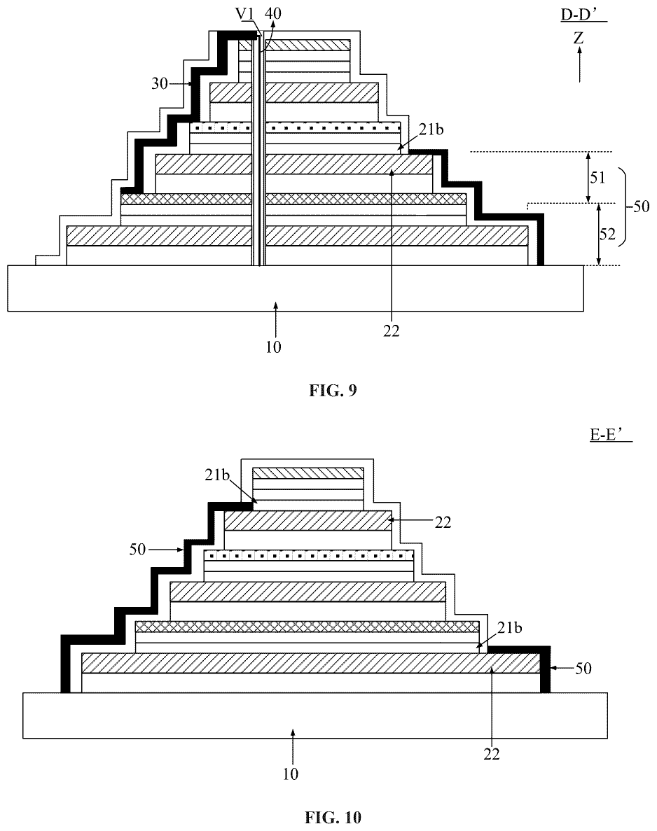

In some embodiments, refer to FIG. 8, FIG. 9, and FIG. 10. FIG. 8 is a top view of a partial structure of yet still another display panel according to some embodiments of the present disclosure. FIG. 9 is a sectional view of FIG. 8 along a line D-D′. FIG. 10 is a sectional view of FIG. 8 along a line E-E′. The display panel further includes a plurality of second metal connectors 50 in one-to-one correspondence with the plurality of light-emitting structures 21 in one of the pixel units 20. The second metal connector 50 is electrically connected to a second semiconductor layer 21b of the light-emitting structures 21 corresponding to this second metal connector, and electrically connected to the substrate 10. In this case, the second metal connector 50 corresponding to each light-emitting structure 21 is provided in each pixel unit 20, and the second metal connector 50 is electrically connected to the second semiconductor layer 21b in the corresponding light-emitting structure 21 and electrically connected to the substrate 10. In this way, electrical signals are provided to the corresponding light-emitting structure 21 separately through each second metal connector 50, such that each light-emitting structure 21 independently emits light. It should be noted that the first metal connector 30 is capable of providing electrical signals to the plurality of light-emitting structures 21 in the pixel unit 20 at the same time, and each of the second metal connectors 50 is capable of providing electrical signals to a corresponding light-emitting structure 21 in the pixel unit 20. In this way, light is emitted from a light-emitting layer between the first semiconductor layer 21a and the second semiconductor layer 21b in the light-emitting structure 21.

In the embodiments of the present disclosure, each pixel unit and the second metal connector are disposed in various optional implementations. The schematic description is given by the following embodiments of the present disclosure using two optional implementations as examples.

In a first optional implementation, as shown in FIG. 9, at least one second metal connector 50 includes a third connection portion 51 and a fourth connection portion 52 that are connected to each other. An orthographic projection of the third connection portion 51 of the second metal connector 50 on the substrate 10 is within the orthographic projection of the pixel unit 20 on the substrate 10, and an orthographic projection of the fourth connection portion 52 of the second metal connector 50 on the substrate 10 is outside the orthographic projection of the pixel unit 20 on the substrate 10. The third connection portion 51 of the second metal connector 50 is electrically connected to the second semiconductor layer 21b of the light-emitting structure 21 corresponding to this second metal connector 50. An end, facing away from the third connection portion 51, of the fourth connection portion 52 of the second metal connector 50 is electrically connected to the substrate 10. In this case, the third connection portion 51 and the fourth connection portion 52 connected to each other are provided in the second metal connector 50, the third connection portion 51 is electrically connected to the second semiconductor layer 21b of the light-emitting structure 21, and the fourth connection portion 52 is electrically connected to the substrate 10. In this way, the substrate 10 is capable of providing electrical signals to the third connection portion 51 over the fourth connection portion 52, and thus the electrical signals are provided to the second semiconductor layer 21b of the light-emitting structure 21. In addition, the third connection portion 51 and the fourth connection portion 52 are both provided at the edge position of the pixel unit, such that the light-emitting area of each light-emitting structure is large. It should be noted that the third connection portion 51 and the fourth connection portion 52 are in a one-piece structure; alternatively, they are formed separately and then fixedly connected by welding or the like.

In some embodiments, as shown in FIGS. 9 and 10, the plurality of second metal connectors 50 in one-to-one correspondence with the plurality of light-emitting structures 21 in one of the pixel units 20 each include the third connection portion 51 and the fourth connection portion 52 that are connected. The orthographic projection of the third connection portion 51 on the substrate 10 is within the orthographic projection of the pixel unit 20 on the substrate 10, and the orthographic projection of the fourth connection portion 52 on the substrate 10 is outside the orthographic projection of the pixel unit 20 on the substrate 10. The third connection portion 51 of the second metal connector 50 is electrically connected to the second semiconductor layer 21b of the corresponding light-emitting structure 21, and the end, facing away from the third connection portion 51, of the fourth connection portion 52 in the second metal connector 50 is electrically connected to the substrate 10.

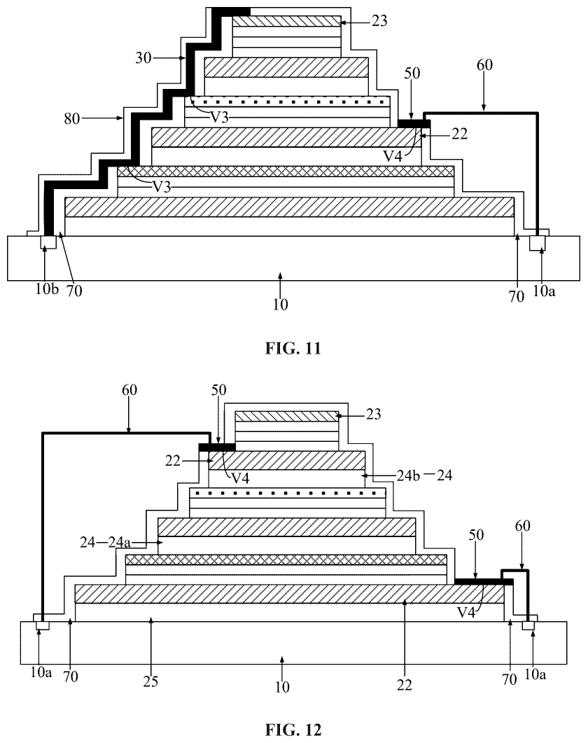

For a second optional implementation, refer to FIG. 11 and FIG. 12. FIG. 11 is a sectional view of a partial structure of a display panel at one view according to some embodiments of the present disclosure. FIG. 12 is a sectional view of a partial structure of a display panel at another viewing angle according to some embodiments of the present disclosure. An orthographic projection of at least one second metal connector 50 in the display panel on the substrate 10 is fully within the orthographic projection of the pixel unit 20 on the substrate 10. The display panel further includes at least one second wire 60. one end of the second wire 60 is electrically connected to the second metal connector 50, and the other end of the second wire 60 is electrically connected to the substrate 10. In this case, by providing the orthographic projection of the second metal connector 50 on the substrate 10 to be fully within the orthographic projection of the pixel unit 20 on the substrate 10 and leading the second metal connector 50 to the substrate 10 by the second wire 60, a length of the second metal connector 50 in the Z-axis direction is reduced, such that the risk of fracture of the second metal connector 50 is reduced. For example, one end of the second wire 60, after being connected to the second metal connector 50, is capable of being electrically connected to the substrate 10 after being bent downward from the outer edge of the pixel unit 20.

Exemplarily, the orthographic projection of each second metal connector 50 on the substrate 10 is within the orthographic projection of the pixel unit 20 on the substrate 10. The at least one second wire 60 is in one-to-one correspondence with the at least one second metal connector 50, and the second metal connector 50 is led to the substrate 10 by the corresponding second wire 60.

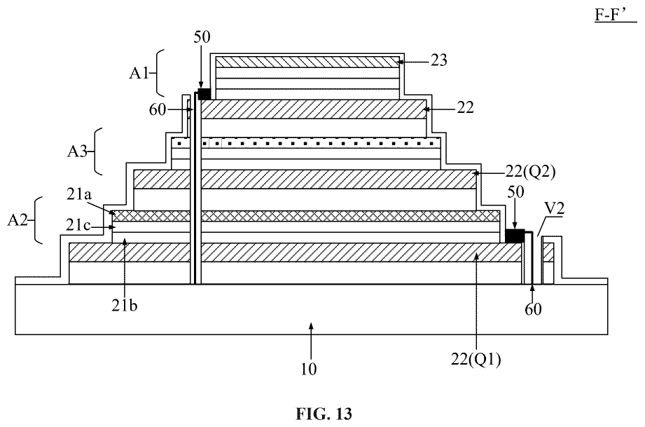

In some embodiments of the present disclosure, refer to FIG. 4 and FIG. 13. FIG. 13 is a sectional view of FIG. 4 along a line F-F′. At least one second through-hole V2 is formed in the pixel unit 20. The second through-hole V2 runs through the light-emitting structure 21 closest to the substrate 10 in the pixel unit 20, and the other end of the second wire 60 is electrically connected to the substrate 10 after running through the second through-hole V2. In this case, by forming the second through-hole V2 in the pixel unit 20, after one end of the second wire 60 is connected to the second metal connector 50, the other end of that is electrically connected to the substrate 10 after running through the second through-hole V2. In this way, the second wire 60 is integrated inside the pixel unit 20, such that the integration degree of the pixel unit is improved. It should be noted that to avoid the undesirable phenomenon of a short circuit caused by the contact between the second wire 60 and an inner wall of the second through-hole V2, an inner diameter of the second through-hole V2 is defined to be larger than an outer diameter of the second wire 60. It should be noted that the arrangement of the second through-hole for different light-emitting structures is further described later.

In some embodiments, as shown in FIG. 13, each pixel unit 20 in the display panel further includes a plurality of drive electrode layers 22, which are in one-to-one correspondence with the plurality of light-emitting structures 21. Each of the drive electrode layers 22 is disposed on a side, close to the substrate 10, of the corresponding light-emitting structure 21, and is lapped with a side, facing away from the first semiconductor layer 21a in this light-emitting structure 21, of the second semiconductor layer 21b in this corresponding light-emitting structure 21. The plurality of drive electrode layers 22 are in one-to-one correspondence with the plurality of second metal connectors 50, and each of the second metal connectors 50 is lapped with the drive electrode layer 22 corresponding to this second metal connector. In this case, each of the drive electrode layers 22 is lapped with the second semiconductor layer 21b in the corresponding light-emitting structure 21 and lapped with the corresponding second metal connector 50. In this way, the substrate 10 is capable of providing electrical signals to the corresponding drive electrode layer 22 over the second metal connector 50, and thus the electrical signals are provided to the second semiconductor layer 21b. In some embodiments, the drive electrode layer 22 is made of a transparent conductive material, such as ITO. It should be noted that in a case where the pixel unit 20 has the second through-hole V2 therein, the second through-hole V2 in the pixel unit 20 at least through the drive electrode layer 22 that is closest to the substrate 10.

In the embodiments of the present disclosure, as shown in FIG. 13, a portion of an orthographic projection of each drive electrode layer 22 on the substrate 10 is outside the orthographic projection of the light-emitting structure 21 corresponding to this drive electrode layer 22 on the substrate 10. At least a portion of the second metal connector 50 is disposed on a side, facing away from the substrate 10, of the corresponding drive electrode layer 22, and is lapped with a portion, not covered by the corresponding light-emitting structure 21, of this drive electrode layer 22. In some embodiments, using the light-emitting structure closest to the substrate 10 as an example, a portion of the orthographic projection of the drive electrode layer 22 corresponding to this light-emitting structure 21 on the substrate 10 is outside the orthographic projection of this light-emitting structure 21 on the substrate 10. At least a portion of the second metal connector 50 is disposed on the side of the drive electrode layer 22 that is backed away from the substrate 10 and lapped with the side, facing away from the substrate 10, of the corresponding drive electrode layer 22 and is lapped with a portion, not covered by the light-emitting structure 21, of the drive electrode layer 22. In this way, the portion, not covered by the light-emitting structure 21, of the drive electrode layer 22 is capable of providing support to at least a portion of the second metal connector 50, which is conductive to providing the second metal connector 50 in the pixel unit 20. It should be noted that where the pixel unit 20 has the second through-hole V2 therein, this second through-hole V2 runs through the drive electrode layer 22 in this light-emitting structure 21, and the second wire 60 is provided within the second through-hole V2.

In some embodiments, as shown in FIG. 13, for a first drive electrode layer Q1 and a second drive electrode layer Q2 adjacent to each other in each pixel unit 20, and a light-emitting structure 21 between the first drive electrode layer Q1 and the second drive electrode layer Q2, an orthographic projection of the light-emitting structure 21 on the substrate 10 is within an orthographic projection of the first drive electrode layer Q1 on the substrate 10, and an orthographic projection of the second drive electrode layer Q2 on the substrate 10 is within the orthographic projection of the light-emitting structure 21 on the substrate 10. The orthographic projections of the first drive electrode layer Q1, the light-emitting structure 21, and the second drive electrode layer Q2 on the substrate 10 are successively reduced. The first drive electrode layer Q1 is closer to the substrate 10 relative to the second drive electrode layer Q2. In this case, the orthographic projections of the first drive electrode layer Q1, the light-emitting structure 21, and the second drive electrode layer Q2 on the substrate 10 decrease successively, therefore, it is possible to form a step-like structure in the pixel unit 20, which facilitates the arrangement of the first metal connector 30 and the second metal connector 50. It should be noted that this light-emitting structure 21 disposed between the first drive electrode layer Q1 and the second drive electrode layer Q2 is a light-emitting structure corresponding to the first drive electrode layer Q1, and a light-emitting structure corresponding to the second drive electrode layer Q2 is disposed on a side, facing away from the first drive electrode layer Q1, of the second drive electrode layer Q2.

In some embodiments of the present disclosure, as shown in FIG. 13, the plurality of light-emitting structures 21 in each pixel unit 20 includes a first light-emitting structure A1 and at least one second light-emitting structure. The first light-emitting structure A1 is a light-emitting structure that is farthest away from the substrate 10 among the plurality of light-emitting structures, and the at least one second light-emitting structure is a light-emitting structure disposed between the first light-emitting structure A1 and the substrate 10. A portion of the first metal connector 30 is disposed on a side, facing away from the substrate 10, of the second light-emitting structure and lapped with a portion, not covered by the second drive electrode layer Q2, of the first semiconductor layer 21a in the second light-emitting structure. In this way, the portion, not covered by the second drive electrode layer Q2, of the first semiconductor layer 21a of the second light-emitting structure is capable of supporting the first metal connector 30, which is conductive to providing the second metal connector 30 in the pixel unit 20.

In the present disclosure, each pixel unit 20 in the display panel includes two second light-emitting structures and the first light-emitting structure A1, which are stacked. The first metal connector 30 is simultaneously electrically connected to the first semiconductor layer 21a of the first light-emitting structure A1 in the corresponding pixel unit 20, the first semiconductor layer 21a of one second light-emitting structure in the corresponding pixel unit 20, and the first semiconductor layer 21a of the other second light-emitting structure A3 in the corresponding pixel unit 20. Based on the light-emitting principle of the display device, the light-emitting wavelengths of one second light-emitting structure A2, the other second light-emitting structure A3, and the first light-emitting structure A1 become progressively shorter. Exemplarily, one second light-emitting structure A2 is a light-emitting structure closest to the substrate 10, and the other second light-emitting structure A3 is a light-emitting structure disposed between the one second light-emitting structure A2 and the first light-emitting structure A1. The color of the light emitted by one second light-emitting structure A2 is red, the color of the light emitted by the other second light-emitting structure A3 is green, and the color of the light emitted by the first light-emitting structure A1 is blue. It should be noted that, exemplarily, as shown in FIGS. 7 and 13, in a case where the pixel unit 20 has the second through-hole V2 therein and the second through-hole V2 provides a mounting path for the second wire 60 in the first light-emitting structure A1, the second through-hole V2 is capable of running through the drive electrode layer 22 in the first light-emitting structure A1, as well as running through both of the second light-emitting structures below. In a case where the pixel unit 20 has the second through-hole V2 therein and the second through-hole V2 is capable of providing a mounting path for the second wire 60 in the other second light-emitting structure A3, the second through-hole V2 is capable of running through the drive electrode layer 22 in the other second light-emitting structure A3, as well as one second light-emitting structure A2 below. In a case where the pixel unit 20 has the second through-hole V2 therein and the second through-hole V2 is capable of providing a mounting path for the second wire 60 in one second light-emitting structure A2, the second through-hole V2 is capable of running through the drive electrode layer 22 in one second light-emitting structure A2.

In some embodiments, as shown in FIG. 13, each pixel unit 20 further includes a common electrode layer 23 disposed on a side, facing away from the substrate 10, of the first light-emitting structure A1. The common electrode layer 23 is lapped with a side, facing away from the second semiconductor layer 21b in the first light-emitting structure A1, of the first semiconductor layer 21a in the first light-emitting structure A1. An orthographic projection of the common electrode layer 23 on the substrate 10 is within an orthographic projection of the first light-emitting structure A1 on the substrate 10. A portion of the first metal connector 30 is disposed on a side, facing away from the first light-emitting structure A1, of the common electrode layer 23, and is lapped with the common electrode layer 23. In this way, in the case where the first metal connector 30 is configured to connect the first semiconductor layers of the respective light-emitting structures, only a common electrode layer with a small area is required to be provided as the common electrode in the pixel unit 20, such that the undesirable phenomenon of the large-step breakage of the common electrode layer is avoided. Exemplarily, a boundary of the orthographic projection of the common electrode layer 23 on the substrate 10 is overlapped with a boundary of an orthographic projection of the first semiconductor layer 21a in the first light-emitting structure A1 on the substrate 10.

In some embodiments of the present disclosure, as shown in FIG. 13, each of the light-emitting structures 21 in the pixel unit 20 includes a first semiconductor layer 21a and a second semiconductor layer 21b that are opposite to each other, and a light-emitting layer 21c disposed between the first semiconductor layer 21a and the second semiconductor layer 21b. The second semiconductor layer 21b is closer to the substrate 10 relative to the first semiconductor layer 21a. For example, using one second light-emitting structure A2 as an example, this second light-emitting structure A2 includes a first semiconductor layer 21a and a second semiconductor layer 21b that are opposite to each other, and a light-emitting layer 21c disposed between the first semiconductor layer 21a and the second semiconductor layer 21b, wherein the second semiconductor layer 21b is disposed closer to the substrate 10 with respect to the first semiconductor layer 21a. For example, the first semiconductor layer 21a is an N-type semiconductor layer in the second light-emitting structure A2, the second semiconductor layer 21b is a P-type semiconductor layer in the second light-emitting structure A2, and the light-emitting layer 21c is a quantum well layer in the second light-emitting structure A2.

One second light-emitting structure A2 emits red light, and in this case, the N-type semiconductor layer in the one second light-emitting structure A2 is AlGalnP or Si, the P-type semiconductor in the one second light-emitting structure A2 is GaP or Mg, and the light-emitting layer in the one second light-emitting structure A2 is AlGalnP or GalnP. The other second light-emitting structure A3 emits green light, and in this case, the N-type semiconductor layer in the other second light-emitting structure A3 is GaN or Si, the P-type semiconductor in the other second light-emitting structure A3 is GaN or Mg, and the light-emitting layer in the other second light-emitting structure A3 is InGaN or GaN. The first light-emitting structure A1 emits blue light, and in this case, the N-type semiconductor layer in the first light-emitting structure A1 is GaN or Si, the P-type semiconductor in the first light-emitting structure A1 is GaN or Mg, and the light-emitting layer in the first light-emitting structure A1 is InGaN or GaN.

In some embodiments, as shown in FIGS. 11 and 12, the display panel further includes a first insulative layer 70. The first insulative layer 70 covers a side surface of the light-emitting structure 21 and covers at least a portion of a surface, facing away from substrate 10, of the light-emitting structure 21. The first insulative layer 70 has a plurality of first vias V3 and a plurality of second vias V4 therein. The first metal connector 30 is electrically connected to the first semiconductor layer 21a of the light-emitting structure 21 through the plurality of first vias V3, and the plurality of second metal connectors 50 are electrically connected to the second semiconductor layers 21b of the plurality of light-emitting structures 21 through the plurality of second vias V4. In this case, the first insulative layer 70 is capable of supporting the first metal connector 30 and the second metal connector 50, and is capable of insulating the first metal connector 30 from structures that do not need to be electrically connected, as well as insulating the second metal connector 50 from structures that do not need to be electrically connected, such that the reliability of the pixel unit 20 is ensured. It should be noted that the plurality of first vias V3 are in one-to-one correspondence with the plurality of light-emitting structures 21, and an orthographic projection of the first via V3 on the substrate 10 is within an orthographic projection of the first semiconductor layer 21a of the corresponding light-emitting structures 21 on the substrate 10. The plurality of second vias V4 are in one-to-one correspondence with the plurality of light-emitting structures 21 and in one-to-one correspondence with the plurality of drive electrode layers 22. An orthographic projection of the second via V4 on the substrate 10 is within an orthographic projection of the corresponding drive electrode layer 22 on the substrate 10, and the second metal connector 50 is electrically connected to the corresponding drive electrode layer 22 through the corresponding second via V4. It should be noted that in a case where a side, facing away from the substrate, of the first semiconductor layer in the first light-emitting structure is provided with a common electrode layer 23, the first metal connector 30 is lapped with the common electrode layer 23 through the first via V3.

In some embodiments of the present disclosure, where the pixel unit 20 has a through-hole therein, the first insulative layer 70 covers an inner wall of the through-hole. In the present disclosure, as shown in FIGS. 9 and 13, where the pixel unit 20 has the first through-hole V1 and/or the second through-hole V2 therein, the first insulative layer 70 covers an inner wall of the first through-hole V1, and a portion, within the first through-hole V1, of the first insulative layer 70 is disposed between a portion, within the first through-hole V1, of the first wire 40 and the inner wall of the first through-hole V1. The first insulative layer 70 covers an inner wall of the second through-hole V2, and a portion, within the second through-hole V2, of the first insulative layer 70 is disposed between a portion, within the second through-hole V2, of the second wire 60 and the inner wall of the second through-hole V2. In this way, the insulative layer provided on the inner wall of the through-hole makes the wires within the through-hole further insulated. In the present disclosure, as shown in FIG. 11, the display panel further includes a second insulative layer 80. The second insulative layer 80 covers a side, facing away from the first insulative layer 70, of the first metal connector 30 and/or the second metal connector 50. In this way, the first metal connector 30 is further protected by the second insulative layer 80, and the second metal connector 50 is further protected by the second insulative layer 80. Exemplarily, the first insulative layer and the second insulative layer are made of the same material, e.g., the insulative layer is made of at least one of SiO2 or SiN.

In some embodiments, as shown in FIG. 12, the pixel unit 20 further includes a transparent bonding layer 24 disposed between adjacent two of the light-emitting structures 21, and a reflective bonding layer 25 disposed between the light-emitting structures 21 and the substrate 10. Exemplarily, the reflective bonding layer 25 is provided between one second light-emitting structure A2 and the substrate 10, and the transparent bonding layer 24a is provided between one second light-emitting structure A2 and the other second light-emitting structure A3, and the transparent bonding layer 24b is provided between the other second light-emitting structure A3 and the first light-emitting structure A1. For example, the reflective bonding layer 25 is provided between the drive electrode layer of one second light-emitting structure A2 and the substrate 10, the transparent bonding layer 24a is provided between the first semiconductor layer 21a of one second light-emitting structure A2 and the drive electrode layer of the other second light-emitting structure A3, and the transparent bonding layer 24b is provided between the first semiconductor layer 21a of the other second light-emitting structure A2 and the drive electrode layer of the first light-emitting structure A1. Exemplarily, the reflective bonding layer 25 is a metal bonding layer, such as at least one of Au—Au bonding, Au—Sn bonding, Au—Ln bonding, Ti—Ti bonding, or Cu—Cu bonding. The transparent bonding layer 24 is made of at least one of transparent plastic, SiO2, or SOG.

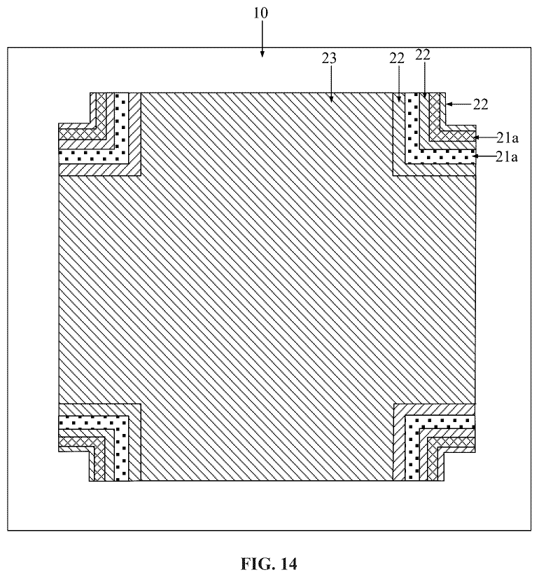

In some embodiments of the present disclosure, as shown in FIG. 2, FIG. 4, FIG. 6, or FIG. 8, for two light-emitting structures 21 adjacent to each other in the pixel unit 20, an outer boundary of an orthographic projection of one of the two light-emitting structures 21 on the substrate 10 is not overlapped with an outer boundary of an orthographic projection of the other light-emitting structure 21 on the substrate 10. Alternatively, refer to FIG. 14, a top view of a partial structure of a display panel according to some embodiments of the present disclosure, an outer boundary of one portion of the orthographic projection of one light-emitting structure 21 on the substrate 10 is overlapped with an outer boundary of one portion of the orthographic projection of the other light-emitting structure 21 on the substrate 10, and an outer boundary of the other portion of the orthographic projection of one light-emitting structure 21 on the substrate 10 is not overlapped with an outer boundary of the other portion of the orthographic projection of the other light-emitting structure 21 on the substrate 10. Exemplarily, the boundary of the orthographic projection of each light-emitting structure 21 in the pixel unit 20 on the substrate 10 is square, and the orthographic projections of the plurality of light-emitting structures 21 on the substrate 10 form a plurality of concentric rings. Alternatively, the boundary of the orthographic projection of each light-emitting structure 21 in the pixel unit 20 on the substrate 10 is square, and notches are formed at corners of the respective light-emitting structures 21, wherein orthographic projections of the notches on the substrate have different areas, such that edge portions of the corners of the respective light-emitting structures 21 are exposed. Boundaries of orthographic projections of portions between every adjacent two corners of the respective light-emitting structures 21 on the substrate 10 are overlapped. It should be noted that the respective light-emitting structures 21 in each pixel unit 20 share a common optical axis.

In some embodiments, as shown in FIGS. 11 and 12, the substrate 10 in the display panel includes a plurality of drive circuits 10a in one-to-one correspondence with the plurality of light-emitting structures in one pixel unit 20, and a common signal connection terminal 10b. The drive circuit 10a is electrically connected to the corresponding light-emitting structure 21 by the second metal connector 50, and at least two first metal connectors 30 are both electrically connected to the common signal connection terminal 10b (it should be noted that only the common signal connection terminal corresponding to one pixel unit is shown in the figures). In this way, the drive circuit 10a is electrically connected to the corresponding light-emitting structure 21 by the second metal connector 50 to transmit electrical signals to the light-emitting structure 21, and electrical signals are provided to the plurality of light-emitting structures 21 in the pixel unit simultaneously by the first metal connector 30 through the common signal connection terminal 10b. Exemplarily, the drive circuit 10a is at least one of a thin-film transistor drive circuit, a low-temperature polysilicon drive circuit, a CMOS integrated circuit drive circuit, or a high mobility transistor drive circuit. In the present disclosure, the drive electrode layer in the light-emitting structure serves as an anode layer in the light-emitting structure, and the common electrode layer serves as a common cathode layer.

In summary, some embodiments of the present disclosure provide a display panel that includes the substrate, the plurality of pixel units, and the first metal connector. The plurality of pixel units arranged in an array are disposed on the substrate, each of the pixel units includes the plurality of light-emitting structures stacked, and the first metal connector corresponding to this pixel unit is electrically connected to the first semiconductor layers of the light-emitting structures in the pixel unit and to the substrate. The first metal connector has a smaller resistance relative to the cathode layer communally provided (e.g., the entire ITO layer), and the conductivity of the first metal connector is high. Therefore, the undesirable phenomenon of a pronounced voltage drop is effectively avoided, such that the brightness of the screen displayed by the display panel is as uniform as possible, and thus the display effect of the display panel is improved. In addition, by providing the first metal connector instead of providing the common electrode layer on the entire layer, the probability of undesirable phenomena such as large-step breakage of the entire common electrode layer is effectively avoided, such that the display panel has a better yield and reliability.

Some embodiments of the present disclosure further provide a method for manufacturing a display panel. The method is applicable to manufacturing the display panel as described above. The method includes the following steps.

In step S1, a plurality of pixel units are formed on a side of a substrate, wherein each of the pixel units includes a plurality of light-emitting structures stacked, and areas of orthographic projections of the plurality of light-emitting structures on the substrate gradually decrease along a direction away from the substrate.

In step S2, a first metal connector is formed, wherein at least two of the pixel units are on one-to-one correspondence with at least two first metal connectors, the first metal connector is electrically connected to a first semiconductor layer of each light-emitting structure in the corresponding pixel unit at the same time, and the first metal connector is electrically connected to the substrate.

In summary, the method for manufacturing the display panel according to some embodiments of the present disclosure includes: forming the plurality of pixel units and the first metal connector on a side of the substrate. The first metal connector has a smaller resistance relative to the cathode layer communally provided (e.g., the entire ITO layer), and the conductivity of the first metal connector is high. Therefore, the undesirable phenomenon of a pronounced voltage drop is effectively avoided, such that the brightness of the screen displayed by the display panel is as uniform as possible, and thus the display effect of the display panel is improved. In addition, by providing the first metal connector instead of providing the common electrode layer on the entire layer, the probability of undesirable phenomena such as large-step breakage of the entire common electrode layer is effectively avoided, such that the display panel has a better yield and reliability.

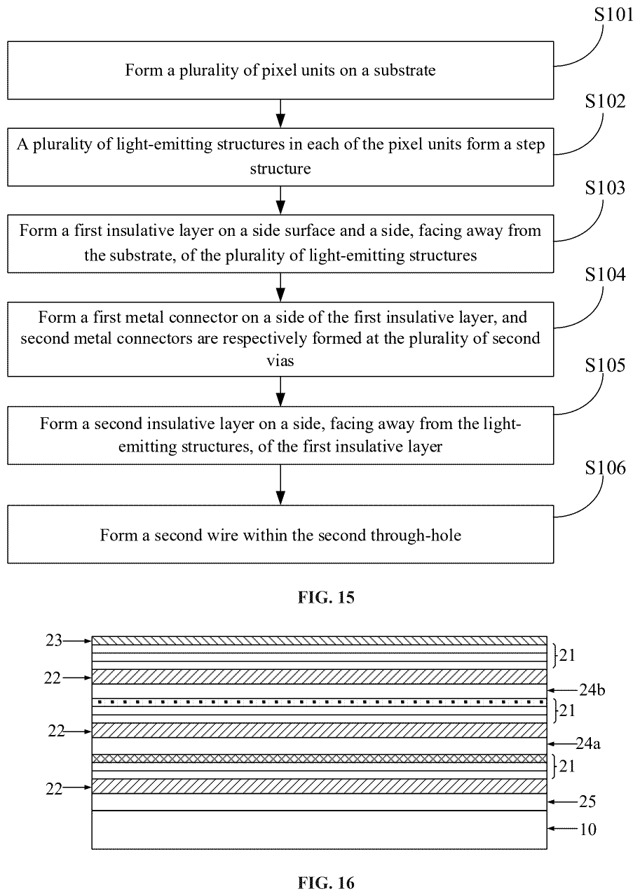

FIG. 15 is a flowchart of a method for manufacturing a display panel according to some embodiments of the present disclosure. Referring to FIG. 15, the method of manufacturing the display panel is applicable to manufacturing the display panel illustrated in FIG. 4. The method for manufacturing the display panel includes the following steps.

In step S101, a plurality of pixel units are formed on a substrate.

Exemplarily, using three light-emitting structures in the pixel unit as an example, refer to FIG. 16, which is a film-layer schematic structural diagram of a pixel unit formed on a substrate according to some embodiments of the present disclosure. Three different light-emitting structures are first formed on three different epitaxial wafers, respectively, and the three light-emitting structures and the substrate are integrally bonded by three bonding layers after the epitaxial wafers are stripped. For example, one second light-emitting structure is bonded to the substrate by a reflective bonding layer, one second light-emitting structure is bonded to the other second light-emitting structure by a transparent bonding layer, and the other second light-emitting structure is bonded to a first light-emitting structure by a transparent bonding layer. It should be noted that for the structures and materials of the one second light-emitting structure, the other second light-emitting structure, the first light-emitting structure, and the bonding layer, references are made to the above embodiments, which are not repeated herein.

In step S102, a plurality of light-emitting structures in each of the pixel units form a step structure.

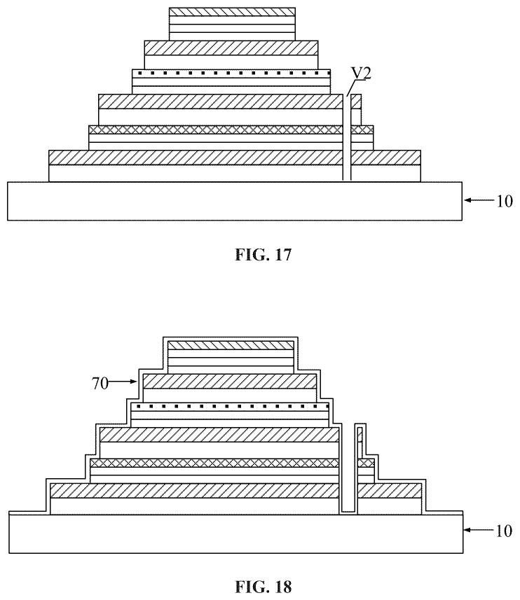

FIG. 17 is a film-layer schematic structural diagram where a step structure is formed according to some embodiments of the present disclosure. Exemplarily, referring to FIG. 17, patterned etch is performed on the three light-emitting structures by performing multiple patterning processes by photolithography or etching, then a first semiconductor layer and a drive electrode layer of each of the light-emitting structures are exposed, and second through-holes corresponding to different light-emitting structures are etched. For example, areas of orthographic projections of the three light-emitting structures on the substrate gradually decrease along the direction away from the substrate. It should be noted that FIG. 17 illustrates the second through-hole corresponding to only one light-emitting structure.

In step S103, a first insulative layer is formed on a side surface and a side, facing away from the substrate, of the plurality of light-emitting structures.

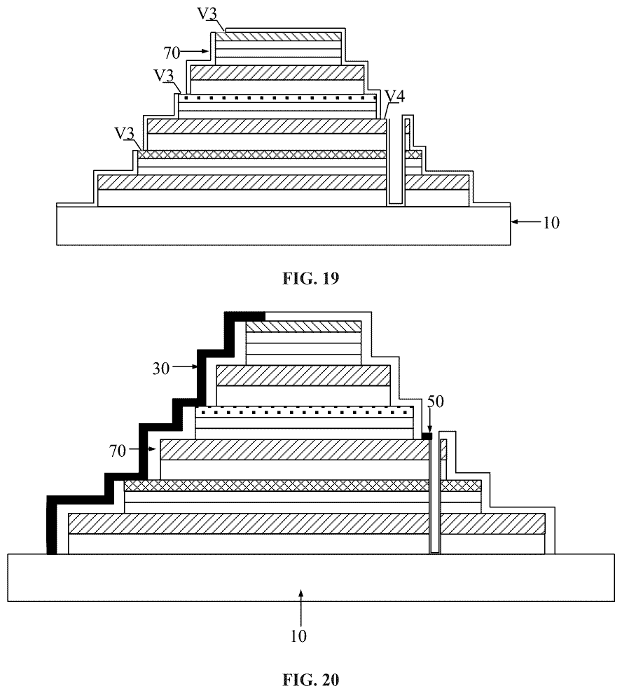

FIG. 18 is a film-layer schematic structural diagram where a first insulative layer is formed according to some embodiments of the present disclosure. Exemplarily, referring to FIG. 18, the first insulative layer is formed on the side surface and the side, facing away from the substrate, of each light-emitting structure by any approach of deposition, coating, sputtering, and the like. Thereafter, referring to FIG. 19, which is a film-layer schematic structural diagram where a plurality of first vias and a plurality of second vias are formed according to some embodiments of the present disclosure, a plurality of first vias and a plurality of second vias are formed by performing a one-time patterning process on this first insulative layer.

In step S104, a first metal connector is formed on a side of the first insulative layer, and second metal connectors are respectively formed at the plurality of second vias.

Exemplarily, referring to FIG. 20, which is a film-layer schematic structural diagram where a first metal connector and a partial second metal connector are formed according to some embodiments of the present disclosure, the first metal connector is formed on the side of the first insulative layer by vapor deposition. The first metal connector is lapped with the first semiconductor layers of the plurality of light-emitting structures through the plurality of first vias and lapped with a common electrode layer by the first semiconductor layer. The plurality of second metal connectors are additionally formed at the plurality of second vias by vapor deposition.

In step S105, a second insulative layer is formed on a side, facing away from the light-emitting structures, of the first insulative layer.

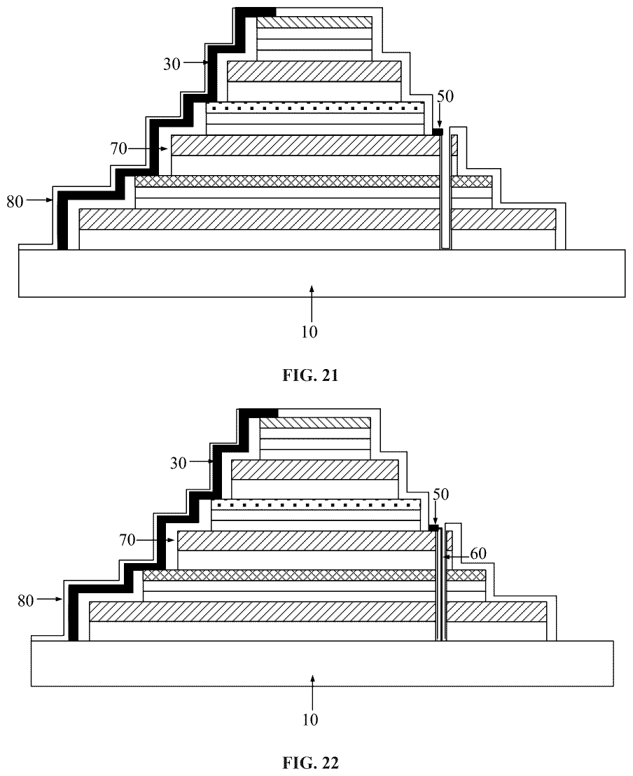

Exemplarily, referring to FIG. 21, which is a film-layer schematic diagram where a second insulative layer is formed according to some embodiments of the present disclosure, the second insulative layer is formed on a side of the first metal connector by any approach of deposition, coating, sputtering, and the like. The first metal connector is protected by the second insulative layer. Then, a position, in contact with the backplane, within the second through-hole is exposed by performing a one-time patterning process. It should be noted that it is possible to form a whole-layered second insulative layer to cover each pixel unit, and the position, in contact with the substrate, within the second through-hole is then exposed by performing the one-time patterning process once.

In step S106, a second wire is formed within the second through-hole.

Exemplarily, referring to FIG. 22, which is a schematic structural diagram where a second wire is formed according to some embodiments of the present disclosure, the second wire is formed by, for example, sputtering. One end of the second wire is electrically connected to the second metal connector, and the other end of the second wire is electrically connected to a drive circuit on the substrate.

It should be noted that the one-time patterning process in the above embodiments includes photoresist coating, exposure, development, and photoresist stripping.

In summary, the method for manufacturing the display panel according to some embodiments of the present disclosure includes: forming the plurality of pixel units and the first metal connector on a side of the substrate. The first metal connector has a smaller resistance relative to the cathode layer communally provided (e.g., the entire ITO layer), and the conductivity of the first metal connector is high. Therefore, the undesirable phenomenon of a pronounced voltage drop is effectively avoided, such that the brightness of the screen displayed by the display panel is as uniform as possible, and thus the display effect of the display panel is improved. In addition, by providing the first metal connector instead of providing the common electrode layer on the entire layer, the probability of undesirable phenomena such as large-step breakage of the entire common electrode layer is effectively avoided, such that the display panel has a better yield and reliability.

Those skilled in the art may clearly understand that, for the convenience and conciseness of the description, the principles of each film layer structure in the above-described display panel may be referred to the corresponding contents in the structural embodiments of the display panel described above, which are not repeated herein.

Some embodiments of the present disclosure further provide a display device, which is a mobile phone, a tablet computer, a television set, a monitor, a laptop computer, a digital photo frame, a navigator, a wearable device, or any product or component with a display function. The display device includes a display panel, which is the display panel as described above.

It should be noted that in the accompanying drawings, the sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

In the present disclosure, the terms “first” and “second” are only used for descriptive purposes, and cannot be understood as indicating or implying relative importance. The term “a plurality of” refers to two or more, unless expressly defined otherwise.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display panel, comprising:
a substrate;
a plurality of pixel units arranged in an array disposed on a side of the substrate, wherein each of the plurality of pixel units comprises a plurality of light-emitting structures stacked, and areas of orthographic projections of the plurality of light-emitting structures on the substrate gradually decrease along a direction away from the substrate; and
at least two first metal connectors in one-to-one correspondence with at least two of the pixel units, wherein each of the first metal connectors is simultaneously electrically connected to a first semiconductor layer of each of the light-emitting structures in the corresponding pixel unit, and the first metal connectors are electrically connected to the substrate;
wherein the substrate is configured to provide a same signal to the at least two first metal connectors.

2. The display panel according to claim 1, wherein the first metal connector comprises a first connection portion and a second connection portion that are connected to each other; wherein
an orthographic projection of the first connection portion on the substrate is within an orthographic projection of the pixel unit on the substrate, and an orthographic projection of the second connection portion on the substrate is outside the orthographic projection of the pixel unit on the substrate; and
the first connection portion is electrically connected to the first semiconductor layer of each of the light-emitting structures in the pixel unit, and an end, facing away from the first connection portion, of the second connection portion is electrically connected to the substrate.

3. The display panel according to claim 1, wherein
an orthographic projection of the first metal connector on the substrate is fully within an orthographic projection of the pixel unit on the substrate; and
the display panel further comprises a first wire, wherein one end of the first wire is electrically connected to the first metal connector, and the other end of the first wire is electrically connected to the substrate.

4. The display panel according to claim 3, wherein a first through-hole running successively through each of the light-emitting structures is formed in the pixel unit, and the other end of the first wire is electrically connected to the substrate after running through the first through-hole.

5. The display panel according to claim 1, further comprising: a plurality of second metal connectors in one-to-one correspondence with the plurality of light-emitting structures in one of the pixel units, wherein each of the second metal connectors is electrically connected to a second semiconductor layer of the corresponding light-emitting structure and electrically connected to the substrate.

6. The display panel according to claim 5, wherein each of the second metal connectors comprises a third connection portion and a fourth connection portion that are connected to each other, wherein
an orthographic projection of the third connection portion on the substrate is within an orthographic projection of the pixel unit on the substrate, and an orthographic projection of the fourth connection portion on the substrate is outside the orthographic projection of the pixel unit on the substrate; and
the third connection portion is electrically connected to the second semiconductor layer of the corresponding light-emitting structure, and an end, facing away from the third connection portion, of the fourth connection portion is electrically connected to the substrate.

7. The display panel according to claim 5, wherein
orthographic projections of the second metal connectors on the substrate are all within an orthographic projection of the pixel unit on the substrate; and
the display panel further comprises a second wire, wherein one end of the second wire is electrically connected to the second metal connector, and the other end of the second wire is electrically connected to the substrate.

8. The display panel according to claim 7, wherein a second through-hole is formed in the pixel unit, wherein the second through-hole runs through at least the light-emitting structure closest to the substrate in the pixel unit, and the other end of the second wire is electrically connected to the substrate after running through the second through-hole.

9. The display panel according to claim 6, wherein the pixel unit further comprises a plurality of drive electrode layers; wherein the plurality of drive electrode layers are in one-to-one correspondence with the plurality of light-emitting structures, each of the drive electrode layers is disposed on a side, close to the substrate, of the corresponding light-emitting structure and lapped with a side, facing away from the first semiconductor layer, of the second semiconductor layer in the corresponding light-emitting structure, the plurality of drive electrode layers are in one-to-one correspondence with the plurality of second metal connectors, and each of the second metal connectors is lapped with the corresponding drive electrode layer.

10. The display panel according to claim 9, wherein
a portion of an orthographic projection of the drive electrode layer on the substrate is outside an orthographic projection of the corresponding light-emitting structure on the substrate; and
at least a portion of the second metal connectors is disposed on a side, facing away from the substrate, of the corresponding drive electrode layer and lapped with a portion, not covered by the corresponding light-emitting structure, of the drive electrode layer.

11. The display panel according to claim 9, wherein for a first drive electrode layer and a second drive electrode layer that are adjacent to each other in the pixel unit and a light-emitting structure disposed between the first drive electrode layer and the second drive electrode layer, an orthographic projection of the light-emitting structure on the substrate is within an orthographic projection of the first drive electrode layer on the substrate, an orthographic projection of the second drive electrode layer on the substrate is within the orthographic projection of the light-emitting structure on the substrate, and the orthographic projections of the first drive electrode layer, the light-emitting structure, and the second drive electrode layer on the substrate successively decrease;
wherein the first drive electrode layer is closer to the substrate relative to the second drive electrode layer.

12. The display panel according to claim 11, wherein
the plurality of light-emitting structures in the pixel unit comprise a first light-emitting structure and at least one second light-emitting structure, the first light-emitting structure being a light-emitting structure, farthest from the substrate, among the plurality of light-emitting structures, and the at least one second light-emitting structure being a light-emitting structure disposed between the first light-emitting structure and the substrate; and
a portion of the first metal connector is disposed on a side, facing away from the substrate, of the second light-emitting structure and lapped with a portion, not covered by the second drive electrode layer, of the first semiconductor layer of the second light-emitting structure.

13. The display panel according to claim 12, wherein the pixel unit further comprises a common electrode layer disposed on a side, facing away from the substrate, of the first light-emitting structure, wherein the common electrode layer is lapped with a side, facing away from the second semiconductor layer, of the first semiconductor layer in the first light-emitting structure, and an orthographic projection of the common electrode layer on the substrate is within an orthographic projection of the first light-emitting structure on the substrate;
wherein a portion of the first metal connector is disposed on a side, facing away from the first light-emitting structure, of the common electrode layer and lapped with the common electrode layer.

14. The display panel according to claim 6, wherein the light-emitting structure comprises the first semiconductor layer and the second semiconductor layer that are opposite to each other and a light-emitting layer disposed between the first semiconductor layer and the second semiconductor layer, the second semiconductor layer being closer to the substrate relative to the first semiconductor layer.

15. The display panel according to claim 6, further comprising: a first insulative layer, the first insulative layer covering a side surface of the light-emitting structure and covering at least a portion of a surface, facing away from the substrate, of the light-emitting structure;
wherein the first insulative layer has a plurality of first vias and a plurality of second vias therein, the first metal connector is electrically connected to the first semiconductor layers of the plurality of light-emitting structures through the plurality of first vias, and the plurality of second metal connectors are electrically connected to the second semiconductor layers of the plurality of light-emitting structures through the plurality of second vias.

16. The display panel according to claim 15, wherein in a case where the pixel unit has a through-hole therein, the first insulative layer covers an inner wall of the through-hole.

17. The display panel according to claim 1, wherein the pixel unit further comprises a transparent bonding layer disposed between adjacent two of the light-emitting structures, and a reflective bonding layer disposed between the light-emitting structure and the substrate.

18. The display panel according to claim 1, wherein for two adjacent light-emitting structures of the light-emitting structures in the pixel unit,
an outer boundary of an orthographic projection of one of the two light-emitting structures on the substrate is not overlapped with an outer boundary of an orthographic projection of the other of the two light-emitting structures on the substrate; alternatively,
an outer boundary of a portion of the orthographic projection of one of the two light-emitting structures on the substrate is overlapped with an outer boundary of a portion of the orthographic projection of the other of the two light-emitting structures on the substrate.

19. The display panel according to claim 6, wherein the substrate comprises a plurality of drive circuits in one-to-one correspondence with the plurality of light-emitting structures in one of the pixel units and a common signal connection terminal, wherein each of the drive circuits is electrically connected to the corresponding light-emitting structure by the second metal connector, and the at least two first metal connectors are all electrically connected to the common signal connection terminal.

20. A display device, comprising: a display panel, wherein the display panel comprises:
a substrate;
a plurality of pixel units arranged in an array disposed on a side of the substrate, wherein each of the plurality of pixel units comprises a plurality of light-emitting structures stacked, and areas of orthographic projections of the plurality of light-emitting structures on the substrate gradually decrease along a direction away from the substrate; and
at least two first metal connectors in one-to-one correspondence with at least two of the pixel units, wherein each of the first metal connectors is simultaneously electrically connected to a first semiconductor layer of each of the light-emitting structures in the corresponding pixel unit, and the first metal connectors are electrically connected to the substrate;
wherein the substrate is configured to provide a same signal to the at least two first metal connectors.
